(19) United States
(12) Patent Application Publication
(10) Pub. No.: US 2014/0191194 A1
(43) Pub. Date: Jul. 10, 2014

(54) NITRIDE SEMICONDUCTOR LIGHT-EMITTING ELEMENT

(71) Applicants: Seok Min Hwang, Pusan (KR); Jae Ho Han, Daejeon (KR); Jae Yoon Kim, Yongin-si (KR); Hae Soo Ha, Suwon-si (KR); Su Yeol Lee, Seongnam-si (KR); Je Won Kim, Seoul (KR)

(72) Inventors: Seok Min Hwang, Pusan (KR); Jae Ho Han, Daejeon (KR); Jae Yoon Kim, Yongin-si (KR); Hae Soo Ha, Suwon-si (KR); Su Yeol Lee, Seongnam-si (KR); Je Won Kim, Seoul (KR)

(73) Assignee: SAMSUNG ELECTRONICS CO., LTD., Suwon-si Gyeonggi-do (KR)

(21) Appl. No.: 14/237,513

(22) PCT Filed: Aug. 9, 2011
(86) PCT No.: PCT/KR2011/005776

§ 371 Date: Feb. 6, 2014

(51) Int. Cl. H01L 33/24; H01L 33/06

(52) U.S. Cl. CPC H01L 33/24; H01L 33/06
USPC 257/13

(57) ABSTRACT

There is provided a nitride semiconductor light emitting device, capable of improving light extraction efficiency through a texture effect and including: a light emitting structure formed on a substrate and including a first conductivity-type nitride semiconductor layer and a second conductivity-type nitride semiconductor layer with an active layer interposed therebetween; a first electrode electrically connected to the first conductivity-type nitride semiconductor layer; a second electrode electrically connected to the second conductivity-type nitride semiconductor layer; and a light extraction pattern disposed between the first electrode and the second electrode and including a plurality of through holes formed by vertically penetrating the light emitting structure.

### TECHNICAL FIELD

The present disclosure relates to a nitride semiconductor light emitting device, and more particularly, to a nitride semiconductor light emitting device with light extraction efficiency improved through a texture effect.

### BACKGROUND ART

A semiconductor light emitting device is a semiconductor device able to emit light of various colors through electron-hole recombination occurring at p-n junctions between p-type and n-type semiconductors when current is applied thereto. A semiconductor light emitting device has various advantages over a filament-based light emitting device, such as relatively long lifespan, relatively low power consumption, superior initial-operating characteristics, high vibration resistance, high tolerance to repeated intermittence of power, and the like; accordingly, demand for semiconductor light emitting devices has continued to grow. In particular, recently, a group III-nitride semiconductor capable of emitting short-wavelength blue light has risen to prominence.

When light generated in an active layer of a semiconductor light emitting device is incident to an interface between air and GaN, the degree of reflection thereof varies according to angle of incidence. Theoretically, in a case in which the angle of incidence is approximately 26° or greater, the light generated in the active layer is totally internally reflected and the totally reflected light escapes from the device through side surfaces of the device or is absorbed or attenuated inside the device, thus serving as a main factor in decreasing light emitting efficiency.

In order to improve light extraction efficiency by overcoming the above-mentioned problem, a technique of forming an uneven pattern on a light emitting surface has been being used. This technique, reducing the total reflection of light using the uneven pattern, may contribute to improving light extraction efficiency to some degree, but a structure to further improve light emitting efficiency is needed.

### DISCLOSURE

### Technical Problem

An aspect of the present disclosure provides a nitride semiconductor light emitting device capable of significantly improving light extraction efficiency using a light extraction pattern formed by removing a part of semiconductor layers at least up to an active layer from a light emitting structure.

### Technical Solution

According to an aspect of the present disclosure, a nitride semiconductor light emitting device may include a light emitting structure formed on a substrate and including a first conductivity-type nitride semiconductor layer, a second conductivity-type nitride semiconductor layer and an active layer interposed therebetween; a first electrode electrically connected to the first conductivity-type nitride semiconductor layer; a second electrode electrically connected to the second conductivity-type nitride semiconductor layer; and a light extraction pattern disposed between the first electrode and the second electrode and including a plurality of through holes formed by vertically penetrating the light emitting structure.

The plurality of through holes may be arranged in a two-dimensional structure. The light extraction pattern further may include at least one first separating groove formed by removing a part of the light emitting structure including at least the active layer in a band shape, and the plurality of through holes may be divided into a plurality of arrays by the first separating groove. The first separating groove may be extended to the first conductivity-type nitride semiconductor layer and the second conductivity-type nitride semiconductor layer.

The light emitting structure may be a mesa-etched structure. The first electrode may be formed on the first conductivity-type nitride semiconductor layer exposed by removing a part of the light emitting structure including at least the active layer.

The nitride semiconductor light emitting device may further include a receiving groove formed by removing a part of the light emitting structure including at least the active layer to expose the first conductivity-type nitride semiconductor layer. The first electrode may be disposed on the first conductivity-type nitride semiconductor layer exposed through the receiving groove, and the plurality of through holes may be arranged in a two-dimensional structure.

The light extraction pattern may further include a second separating groove formed by removing a part of the light emitting structure including at least the active layer in a band shape and separating the first and second electrodes from side surfaces of the light emitting structure.

The light extraction pattern may further include a plurality of second through holes formed between the second separating groove and the side surfaces of the light emitting structure by vertically penetrating the light emitting structure, and the plurality of second through holes may be disposed along the perimeter of the light emitting structure.

Each of the plurality of through holes may include a first groove formed by removing a part of the light emitting structure including at least the active layer, and at least one second groove formed by penetrating the first conductivity-type nitride semiconductor layer from a bottom surface of the first groove. The light extraction pattern may further include a plurality of third grooves formed by penetrating the exposed first conductivity-type nitride semiconductor layer along the perimeter of the mesa-etched structure.

The substrate may include a pattern formed therein.

### Advantageous Effects

As set forth above, according to exemplary embodiments of the present disclosure, light extraction efficiency of a nitride semiconductor light emitting device may be further improved through a texture effect caused by an uneven structure formed between n-type and p-type electrodes by penetrating a part of a light emitting structure from a top surface thereof to a bottom surface thereof.

### DESCRIPTION OF DRAWINGS

FIG. 1 is a schematic perspective view illustrating a nitride semiconductor light emitting device according to a first exemplary embodiment of the present disclosure;

FIG. 2 is a side cross-sectional view illustrating the nitride semiconductor light emitting device of FIG. 1, taken along line X-X′;

FIG. 3 is a side cross-sectional view illustrating another example of the nitride semiconductor light emitting device of FIG. 1;

FIG. 4 is a schematic perspective view illustrating a nitride semiconductor light emitting device according to a second exemplary embodiment of the present disclosure;

FIG. 5 is a side cross-sectional view illustrating the nitride semiconductor light emitting device of FIG. 4, taken along line X-X′;

FIG. 6 is a schematic perspective view illustrating a nitride semiconductor light emitting device according to a third exemplary embodiment of the present disclosure;

FIG. 7 is a side cross-sectional view illustrating the nitride semiconductor light emitting device of FIG. 6, taken along line X-X′;

FIG. 8 is a schematic perspective view illustrating a nitride semiconductor light emitting device according to a fourth exemplary embodiment of the present disclosure;

FIG. 9 is a side cross-sectional view illustrating the nitride semiconductor light emitting device of FIG. 8, taken along line X-X′;

FIG. 10 is a schematic perspective view illustrating a nitride semiconductor light emitting device according to a fifth exemplary embodiment of the present disclosure;

FIG. 11 is a side cross-sectional view illustrating the nitride semiconductor light emitting device of FIG. 10, taken along line X-X′;

FIG. 12 is a schematic perspective view illustrating a nitride semiconductor light emitting device according to a sixth exemplary embodiment of the present disclosure; and

FIG. 13 is a side cross-sectional view illustrating the nitride semiconductor light emitting device of FIG. 12, taken along line X-X′.

### BEST MODE

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

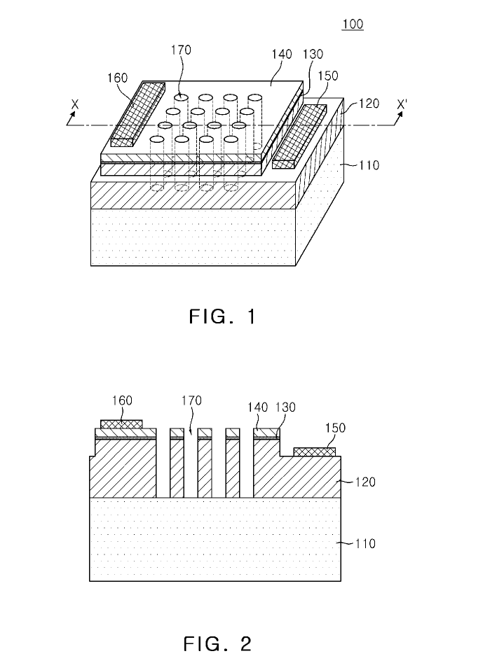

FIG. 1 is a schematic perspective view illustrating a nitride semiconductor light emitting device according to a first exemplary embodiment of the present disclosure, and FIG. 2 is a side cross-sectional view illustrating the nitride semiconductor light emitting device of FIG. 1, taken along line X-X′.

With reference to FIGS. 1 and 2, a nitride semiconductor light emitting device 100 according to the first exemplary embodiment of the present disclosure may include a substrate 110, a light emitting structure formed on the substrate 110 and including an n-type semiconductor layer 120, an active layer 130 and a p-type semiconductor layer 140, and a light extraction pattern 170 formed by removing a part of the light emitting structure at least up to the active layer 130. An n-type electrode 150 and a p-type electrode 160 may be provided to be electrically connected to the n-type semiconductor layer 120 and the p-type semiconductor layer 140, respectively. In addition, the p-type semiconductor layer 140 and the active layer 130 may be mesa-etched to be disposed on a part of the n-type semiconductor layer 120. Accordingly, a part of the n-type semiconductor layer 120 may be exposed, and the n-type electrode 150 may be formed on the exposed surface of the n-type semiconductor layer 120.

Here, a substrate 110 may be used for growing nitride semiconductor layers. The substrate 110 may be a high resistance substrate, and a sapphire substrate may mainly be used therefor. Sapphire is a crystal having Hexa-Rhombo Ric symmetry and has a lattice constant of 13.001 Å along a C-axis and a lattice constant of 4.758 Å along an A-axis. Crystal planes of sapphire include a C (0001) plane, an A (1120) plane, an R (1102) plane, and the like. The C plane is mainly used as a substrate for nitride semiconductor growth because it facilitates the growth of a nitride film and is stable at high temperatures. However, the substrate 110 according to the present embodiment is not limited to the sapphire substrate, and a substrate made of SiC, Si, GaN, AIN or the like, besides the sapphire substrate, may also be used.

Although not shown, a buffer layer (not shown) may be formed on the substrate 110 in order to alleviate a lattice mismatch between the substrate 110 and the n-type semiconductor layer 120. The buffer layer may be an n-type material layer or an undoped material layer formed of group III-V nitride compound semiconductors. The buffer layer may be a nucleation layer grown at low temperatures including AIN or n-GaN.

The n-type and p-type semiconductor layers 120 and 140 may be formed of a semiconductor material having a composition expressed by AlₓIn_{y}Ga_{(1-x-y)}N, where 0≦x≦1, 0≦y≦1, and 0≦x+y≦1, and doped with n-type and p-type impurities, respectively. The semiconductor materials may be GaN, AlGaN, and InGaN. In addition, Si, Ge, Se, Te or C may be used as the n-type impurities, and Mg, Zn or Be may be used as the p-type impurities. The n-type and p-type semiconductor layers 120 and 140 may be formed by using a nitride semiconductor growth method known in the art. For example, the n-type and p-type semiconductor layers 120 and 140 may be grown by metal organic chemical vapor deposition (MOCVD), molecular beam epitaxy (MBE), hydride vapor phase epitaxy (HVPE), or the like.

The active layer 130 may be a material layer emitting light through electron-hole carrier recombination and may be formed of GaN-based group III-V nitride compound semiconductor layers having a multi-quantum well (MQW) structure in which quantum well layers and quantum barrier layers are alternately stacked. Here, the quantum barrier layers may have a composition expressed by AlₓIn_{y}Ga_{(1-x-y)}N, where 0≦x≦1, 0≦y≦1, and 0<x+y≦1, and the quantum well layers may have a composition expressed by In_{z}Ga_{(1-z)}N, where 0≦z≦1. Here, the quantum barrier layers may have a superlattice structure having a thickness allowing tunneling of holes injected from the p-type semiconductor layer 140.

The n-type electrode 150 may be formed on the n-type semiconductor layer 120 exposed by mesa-etching the p-type semiconductor layer 140 and the active layer 130, and the p-type electrode 160 may be formed on the p-type semiconductor layer 140. The n-type electrode 150 and the p-type electrode 160 may be disposed as far away from one another as possible to induce current spreading. In addition, the n-type electrode 150 and the p-type electrode 160 may be formed of a material having high light reflectivity in order to allow light generated in the active layer 130 to be reflected instead of being absorbed by the electrodes, and for example, Al, Ag or the like may be used as the electrodes.

The light extraction pattern 170 may be disposed between the n-type electrode 150 and the p-type electrode 160 and may include a plurality of through holes formed by vertically penetrating the light emitting structure. The plurality of through holes may be arranged in a two-dimensional structure and extend from the n-type semiconductor layer 120 to the p-type semiconductor layer 140. The through holes may expose portions of the substrate 110 therebelow.

The light extraction pattern 170 may be formed by using a mask pattern or by etching. The method of forming the light extraction pattern 170 is not particularly limited. Various etching techniques such as E-beam lithography, photolithography or the like may be used. For example, after a mask pattern is formed on the top surface of the p-type semiconductor layer 140 to define the light extraction pattern 170, the p-type semiconductor layer 140, the active layer 130 and the n-type semiconductor layer 120 are etched using the mask pattern as an etching mask to thereby form the through holes through which corresponding portions of the substrate are exposed. As a result, the light extraction pattern 170 may be disposed adjacent to a light emitting region. Here, a cross-section of the through hole may be circular as illustrated, or may have various shapes such as a quadrangular shape, a hexagonal shape, or the like.

The light extraction pattern 170 may improve light extraction efficiency by decreasing light loss caused by total internal reflection and reflection of light. That is, the light repeating internal reflection may be emitted outwardly through the light extraction pattern 170 adjacent to the light emitting region, whereby the light loss caused by the internal reflection may be prevented and the light extraction efficiency may be improved. In addition, the light extraction pattern 170 may form a barrier with respect to a current flow direction, thereby reducing the concentration of current on a central portion of the light emitting device between the n-type electrode 150 and the p-type electrode 160 and improving current spreading.

In the nitride semiconductor light emitting device 100 according to the first embodiment of the present disclosure, the light emitting region may be reduced due to removal of a part of the semiconductor layers at least up to the active layer 130 from the top surface of the light emitting structure, but the light extraction pattern may be provided throughout the entirety of the light emitting structure between the n-type and p-type electrodes in order to increase the amount of light emitted outwardly, whereby light extraction efficiency may be further improved.

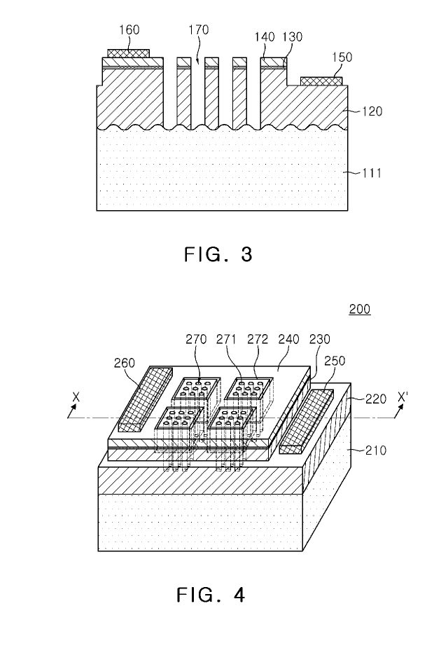

FIG. 3 is a side cross-sectional view illustrating another example of the nitride semiconductor light emitting device of FIG. 1. Here, the nitride semiconductor light emitting device of FIG. 3 has substantially the same configuration as that of the nitride semiconductor light emitting device of FIGS. 1 and 2, except that it uses a patterned sapphire substrate (PSS). Therefore, a redundant description of the same configuration will be omitted, and only details related to different configurations will be provided.

With reference to FIG. 3, the nitride semiconductor light emitting device according to the exemplary embodiment of the present disclosure may use a PSS 111 as a substrate, such that the PSS 111 may efficiently allow for the light generated in the active layer 130 to undergo diffused reflection and travel toward a light emitting surface, whereby light extraction efficiency may be improved. The PSS 111 may have a regular pattern formed therein, but is not limited thereto. An irregular pattern may be formed in the PSS. In addition, a cross-section of the pattern may be triangular or convexly rounded.

With reference to FIGS. 4 through 13, modified examples of the nitride semiconductor light emitting device of FIG. 1 will be described. Here, in a description of nitride semiconductor light emitting devices illustrated in FIGS. 4 through 13, details related to the same configuration as that of the nitride semiconductor light emitting device 100 according to the first exemplary embodiment illustrated in FIGS. 1 and 2 will be omitted, and only details related to different configurations will be provided.

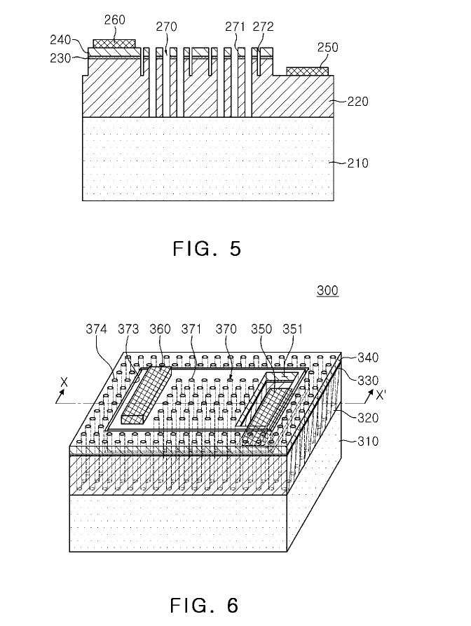

FIG. 4 is a schematic perspective view illustrating a nitride semiconductor light emitting device according to a second exemplary embodiment of the present disclosure, and FIG. 5 is a side cross-sectional view illustrating the nitride semiconductor light emitting device of FIG. 4, taken along line X-X′.

With reference to FIGS. 4 and 5, a nitride semiconductor light emitting device 200 according to the second exemplary embodiment of the present disclosure may include a light extraction pattern 270 formed between an n-type electrode 250 and a p-type electrode 260. Here, the n-type electrode 250 may be formed on an n-type semiconductor layer 220 exposed by mesa-etching a p-type semiconductor layer 240 and an active layer 230 of a light emitting structure and the p-type electrode 260 may be formed on the p-type semiconductor layer 240.

The light extraction pattern 270 may include a groove 272 dividing a top surface of the light emitting structure into at least one or more regions and a plurality of through holes 271 disposed within the regions separated by the groove 272 and formed by removing a part of the light emitting structure at least up to the active layer 230. The groove 272 may surround the plurality of through holes 271 and divide the plurality of through holes 271 into a plurality of arrays. The groove 272 may be formed in a band shape by removing a part of the light emitting structure at least up to the active layer 230.

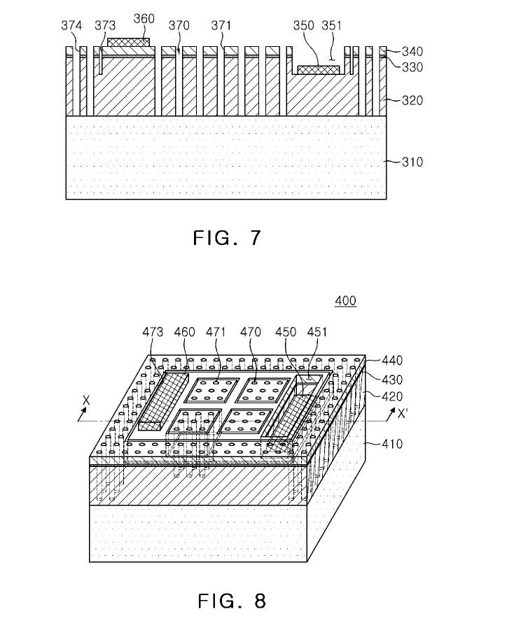

FIG. 6 is a schematic perspective view illustrating a nitride semiconductor light emitting device according to a third exemplary embodiment of the present disclosure, and FIG. 7 is a side cross-sectional view illustrating the nitride semiconductor light emitting device of FIG. 6, taken along line X-X′.

With reference to FIGS. 6 and 7, a nitride semiconductor light emitting device 300 according to the third exemplary embodiment of the present disclosure may include a light emitting structure formed on a substrate 310 and including an n-type semiconductor layer 320, an active layer 330 and a p-type semiconductor layer 340, and an n-type electrode 350 and a p-type electrode 360 electrically connected to the n-type semiconductor layer 320 and the p-type semiconductor layer 340, respectively. Here, the n-type electrode 350 may be formed on the n-type semiconductor layer 320 exposed through a receiving groove 351 formed by removing a part of the light emitting structure at least up to the active layer 330. In addition, the nitride semiconductor light emitting device 300 according to the embodiment of the present disclosure may include a light extraction pattern 370 formed by removing a part of the light emitting structure at least up to the active layer 330.

In the present embodiment, the light extraction pattern 370 may include a plurality of first through holes 371 formed by vertically penetrating the light emitting structure between the n-type electrode 350 and the p-type electrode 360, a groove 373 spaced apart from side surfaces of the light emitting structure and formed along the side surfaces in a band shape, and a plurality of second through holes 374 disposed between the side surfaces of the light emitting structure and the groove 373. As illustrated, the plurality of through holes 371 and 374 may be formed by vertically penetrating the light emitting structure, and the groove 373 may be formed by removing a part of the n-type semiconductor layer 320 such that the n-type semiconductor layer 320 forms a bottom surface of the groove 373. In addition, the second through holes 374 may be disposed in an entirety of the perimeter of the light emitting structure along the side surfaces as illustrated, or may be disposed in a part of the perimeter thereof.

A light travelling toward a light emitting surface among light generated in the active layer 330 is emitted outwardly or internally reflected, and The light extraction pattern 370 may allow the reflected light and light traveling toward the substrate to be refracted or be deflected toward the light emitting surface to be emitted outwardly. Accordingly, light extraction efficiency may be further improved.

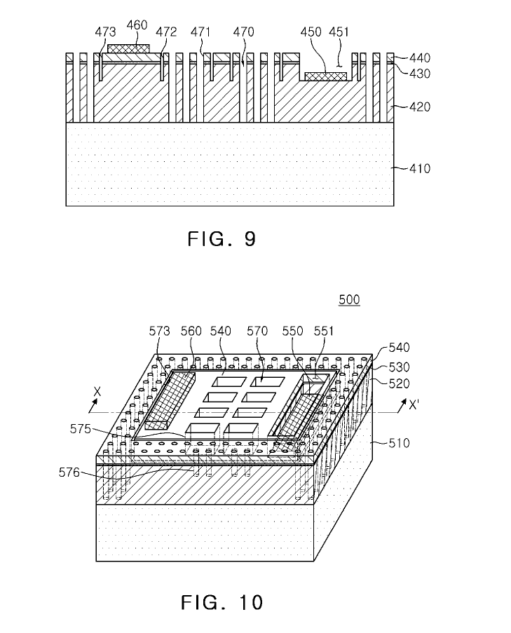

FIG. 8 is a schematic perspective view illustrating a nitride semiconductor light emitting device according to a fourth exemplary embodiment of the present disclosure, and FIG. 9 is a side cross-sectional view illustrating the nitride semiconductor light emitting device of FIG. 8, taken along line X-X′.

With reference to FIGS. 8 and 9, a nitride semiconductor light emitting device 400 according to the fourth exemplary embodiment of the present disclosure may include a light emitting structure formed on a substrate 410 and including an n-type semiconductor layer 420, an active layer 430 and a p-type semiconductor layer 440, and an n-type electrode 450 and a p-type electrode 460 electrically connected to the n-type semiconductor layer 420 and the p-type semiconductor layer 440, respectively. Here, the n-type electrode 450 may be formed on the n-type semiconductor layer 420 exposed through a groove 451 formed by removing a part of the light emitting structure at least up to the active layer 430. In addition, the nitride semiconductor light emitting device 400 according to the embodiment of the present disclosure may include a light extraction pattern 470 formed by removing a part of the light emitting structure at least up to the active layer 430.

In the present embodiment, the light extraction pattern 470 may include a first groove 472 formed in a band shape in order to divide a top surface of the light emitting structure into at least one or more regions, a plurality of first through holes 471 disposed within the regions divided by the groove 472 and formed by vertically penetrating the light emitting structure, a second groove 473 formed along the perimeter of the light emitting structure in a band shape, and a plurality of second through holes 474 formed between side surfaces of the light emitting structure and the respective electrodes. The first groove 472 may surround the plurality of first through holes 471 and divide the plurality of first through holes into a plurality of arrays. The second groove 473 may be spaced apart from the side surfaces of the light emitting device 400 and be disposed along the perimeter of the light emitting structure, and may separate the second through holes 474 from the respective electrodes.

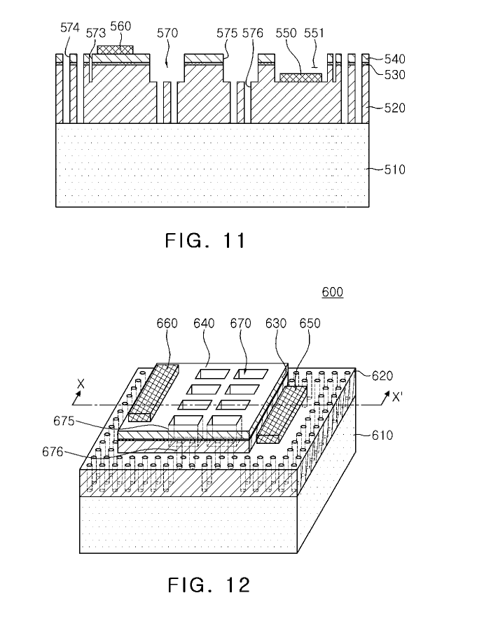

FIG. 10 is a schematic perspective view illustrating a nitride semiconductor light emitting device according to a fifth exemplary embodiment of the present disclosure, and FIG. 11 is a side cross-sectional view illustrating the nitride semiconductor light emitting device of FIG. 10, taken along line X-X′.

With reference to FIGS. 10 and 11, a nitride semiconductor light emitting device 500 according to the fifth exemplary embodiment of the present disclosure may include a light emitting structure formed on a substrate 510 and including an n-type semiconductor layer 520, an active layer 530 and a p-type semiconductor layer 540, and an n-type electrode 550 and a p-type electrode 560 electrically connected to the n-type semiconductor layer 520 and the p-type semiconductor layer 540, respectively. Here, the n-type electrode 550 may be formed on the n-type semiconductor layer 520 exposed through a receiving groove 551 formed by removing a part of the light emitting structure at least up to the active layer 530. In addition, the nitride semiconductor light emitting device 500 according to the embodiment of the present disclosure may include a light extraction pattern 570 formed by removing a part of the light emitting structure at least up to the active layer 530.

In the present embodiment, the light extraction pattern 570 may include a plurality of first through holes formed by vertically penetrating a part of the light emitting structure between the n-type electrode 550 and the p-type electrode 560 and having a dual structure, a groove 573 formed in a band shape at an outer side of each of the electrodes along the perimeter of the light emitting structure, and a plurality of second through holes 574 formed between side surfaces of the light emitting structure and the respective electrodes. Here, each of the first through holes having the dual structure may include a first groove 575 formed by removing a part of the light emitting structure at least up to the active layer 530 and a second groove 576 formed by removing a part of the n-type semiconductor layer 520 from a bottom surface of first groove 575.

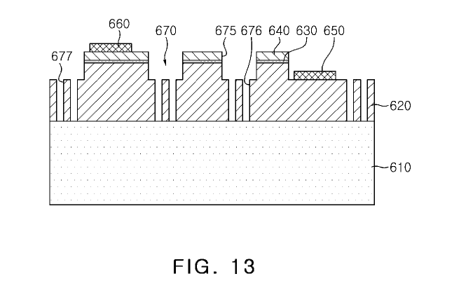

FIG. 12 is a schematic perspective view illustrating a nitride semiconductor light emitting device according to a sixth exemplary embodiment of the present disclosure, and FIG. 13 is a side cross-sectional view illustrating the nitride semiconductor light emitting device of FIG. 12, taken along line X-X′.

With reference to FIGS. 12 and 13, a nitride semiconductor light emitting device 600 according to the sixth exemplary embodiment of the present disclosure may include a light emitting structure formed on a substrate 610 and including an n-type semiconductor layer 620, an active layer 630 and a p-type semiconductor layer 640, and an n-type electrode 650 and a p-type electrode 660 electrically connected to the n-type semiconductor layer 620 and the p-type semiconductor layer 640, respectively. Here, the n-type electrode 650 may be formed on the n-type semiconductor layer 620 exposed by mesa-etching a part of the light emitting structure including the p-type semiconductor layer 640 and the active layer 630. In addition, the nitride semiconductor light emitting device 600 according to the embodiment of the present disclosure may include a light extraction pattern 670 formed by removing a part of the light emitting structure at least up to the active layer 630.

In the present embodiment, the light extraction pattern 670 may include a plurality of through holes formed by vertically penetrating a part of the light emitting structure between the n-type electrode 650 and the p-type electrode 660 and having a dual structure, and a plurality of third grooves 677 formed in the n-type semiconductor layer 620 exposed by the mesa-etching process. Here, each of the plurality of through holes having the dual structure may include a first groove 675 formed by removing a part of the light emitting structure at least up to the active layer 630 and a plurality of second grooves 676 formed by removing a part of the n-type semiconductor layer 620 from a bottom surface of first groove 675. The plurality of third grooves 677 may be formed to expose the substrate 610 therebelow.

While exemplary embodiments have been shown and described above, it will be apparent to those skilled in the art that modifications and variations could be made without departing from the spirit and scope of the present disclosure as defined by the appended claims.

1. A nitride semiconductor light emitting device, comprising:
a light emitting structure formed on a substrate and including a first conductivity-type nitride semiconductor layer, a second conductivity-type nitride semiconductor layer and an active layer interposed therebetween;
a first electrode electrically connected to the first conductivity-type nitride semiconductor layer;
a second electrode electrically connected to the second conductivity-type nitride semiconductor layer; and
a light extraction pattern disposed between the first electrode and the second electrode and including a plurality of through holes formed by vertically penetrating the light emitting structure.

2. The nitride semiconductor light emitting device of claim 1, wherein the plurality of through holes are arranged in a two-dimensional structure.

3. The nitride semiconductor light emitting device of claim 1, wherein the light extraction pattern further includes at least one first separating groove formed by removing a part of the light emitting structure including at least the active layer in a band shape, and
the plurality of through holes are divided into a plurality of arrays by the first groove.

4. The nitride semiconductor light emitting device of claim 3, wherein the first separating groove is extended to the first conductivity-type nitride semiconductor layer and the second conductivity-type nitride semiconductor layer.

5. The nitride semiconductor light emitting device of claim 1, wherein the light emitting structure is a mesa-etched structure.

6. The nitride semiconductor light emitting device of claim 5, wherein the first electrode is formed on the first conductivity-type nitride semiconductor layer exposed by removing a part of the light emitting structure including at least the active layer.

7. The nitride semiconductor light emitting device of claim 5, wherein each of the plurality of through holes includes a first groove formed by removing a part of the light emitting structure including at least the active layer and at least one second groove formed by penetrating a part of the first conductivity-type nitride semiconductor layer from a bottom surface of the first groove.

8. The nitride semiconductor light emitting device of claim 7, wherein the light extraction pattern further includes a plurality of third grooves formed by penetrating the exposed first conductivity-type nitride semiconductor layer along the perimeter of the mesa-etched structure.

9. The nitride semiconductor light emitting device of claim 1, further comprising a receiving groove formed by removing a part of the light emitting structure including at least the active layer to expose the first conductivity-type nitride semiconductor layer,
wherein the first electrode is disposed on the first conductivity-type nitride semiconductor layer exposed through the receiving groove.

10. The nitride semiconductor light emitting device of claim 9, wherein the plurality of through holes are arranged in a two-dimensional structure.

11. The nitride semiconductor light emitting device of claim 9, wherein the light extraction pattern further includes a second separating groove formed by removing a part of the light emitting structure including at least the active layer in a band shape and separating the first and second electrodes from side surfaces of the light emitting structure.

12. The nitride semiconductor light emitting device of claim 11, wherein the light extraction pattern further includes a plurality of second through holes formed between the second separating groove and the side surfaces of the light emitting structure by vertically penetrating the light emitting structure.

13. The nitride semiconductor light emitting device of claim 12, wherein the plurality of second through holes are disposed along the perimeter of the light emitting structure.

14. The nitride semiconductor light emitting device of claim 13, wherein each of the plurality of through holes includes a first groove formed by removing a part of the light emitting structure including at least the active layer, and at least one second groove formed by penetrating a part of the first conductivity-type nitride semiconductor layer from a bottom surface of the first groove.

15. The nitride semiconductor light emitting device of claim 1, wherein the substrate includes a pattern formed therein.

16. The nitride semiconductor light emitting device of claim 3, wherein the light emitting structure is a mesa-etched structure.

17. The nitride semiconductor light emitting device of claim 3, further comprising a receiving groove formed by removing a part of the light emitting structure including at least the active layer to expose the first conductivity-type nitride semiconductor layer,
wherein the first electrode is disposed on the first conductivity-type nitride semiconductor layer exposed through the receiving groove.
